(19) United States
(12) Patent Application Publication
(10) Pub. No.: US 2018/0264621 A1
(43) Pub. Date: Sep. 20, 2018

(54) RETAINER RING FOR CARRIER HEAD FOR CHEMICAL POLISHING APPARATUS AND CARRIER HEAD COMPRISING SAME

(71) Applicant: Hyun Jeong Yoo, Gyeonggi-do (KR)

(72) Inventor: Hyun Jeong Yoo, Gyeonggi-do (KR)

(21) Appl. No.: 15/532,964

(22) PCT Filed: Nov. 17, 2015
(86) PCT No.: PCT/KR2015/012336

§ 371 Date: Jun. 2, 2017

(30) Foreign Application Priority Data
Dec. 8, 2014 (KR) 10-2014-0175039
Jul. 28, 2015 (KR) 10-2015-0106319

(51) Int. Cl. B24B 37/32; H01L 21/687

(52) U.S. Cl. CPC B24B 37/32; H01L 21/68721

(57) ABSTRACT

Provided is a retainer ring of a carrier head for a chemical polishing apparatus, including a first retainer ring member that touches an outer side surface of a wafer, a second retainer ring member that is provided on an outer side and top of the first retainer ring member and does not touch the outer side surface of the wafer, and a pressure reducing means for reducing the pressure transmitted from the second retainer ring member down to the first retainer ring member.

### TECHNICAL FIELD

The present disclosure relates to a retainer ring of a carrier head for a chemical polishing apparatus and a carrier head comprising the same.

### BACKGROUND ART

An integrated circuit is generally formed on a substrate, in particular, a silicon wafer by subsequently depositing conducting, semiconducting or insulating layers. After each layer is deposited, the layers are etched to produce circuit properties. As a series of layers are subsequently deposited and etched, the outer or top surface of the substrate, i.e., the exposed surface of the substrate gradually becomes non-planar. The non-planar outer surface is a problem to integrated circuit manufacturers. If the outer surface of the substrate is not a plane, a photoresist layer placed thereon is not a plane too.

The photoresist layer is generally patterned by photolithographic devices that focus an optical image on a photoresist. If the outer surface of the substrate is too uneven, a maximum height difference between peak and valley of the outer surface will exceed the focus depth of the imaging device, failing to appropriately focus an optical image onto the outer surface of the substrate. Designing novel photolithographic devices with improved focus depth is a very costly task. Furthermore, as the minimum wire width used in the integrated circuit is smaller, shorter light wavelengths should be used, and thus available focus depth is further reduced. Accordingly, the substrate surface needs to be periodically planarized so as to provide a substantially planar surface.

Chemical Mechanical Polishing (hereinafter CMP) is one method for planarization, and for CMP, a target wafer (substrate) is mounted on a polishing head, and mounting of the substrate on the polishing head is accomplished by contact of a flexible thin film mounted on the lower surface of the polishing head with the substrate. Subsequently, as the substrate mounted on the head comes into contact with the flexible thin film, the surface opposite to the contact surface with the flexible thin film comes into contact with a rotating polishing pad. In this instance, the head presses the substrate against the polishing pad, and the head rotates to provide an additional movement between the substrate and the polishing pad. A polishing slurry including abrasive and at least one chemical reactant is distributed on the polishing pad so that the abrasive chemical solution is supplied to the interface between the pad and the substrate. This CMP process is very complex, and is different from simple wet sanding. In the CMP process, the reactant in the slurry reacts with the outer surface of the substrate to form a reaction site. Polishing is accomplished by interaction between the polishing pad having the reaction site and the abrasive particles.

Particularly, in the CMP process, the polishing rate, the extent of finish and flatness are determined by a combination of the pad and the slurry, a relative velocity between the substrate and the pad, and a pressing force to press the substrate against the pad. If flatness and the extent of finish are insufficient, the substrate is defective, so a combination of the polishing pad and the slurry is selected by the extent of finish and flatness required. Under this condition, the maximum throughput of the polishing device is set by the polishing rate. The polishing rate varies depending on the force causing the substrate to be compressed against the pad. Particularly, as the force is greater, the polishing rate is faster. If the carrier head applies a non-uniform load, i.e., the carrier head is pressed by a greater force at only certain areas of the substrate, higher pressure areas will be polished faster than lower pressure areas. Thus, if the load is non-uniform, the substrate will be unevenly polished. Furthermore, one problem of the CMP process is that the edge of the substrate is often polished at different speeds (generally faster and sometimes slower) from the center of the substrate.

This problem called “edge effect” also occurs when the load is uniformly applied to the substrate. The edge effect generally occurs at the peripheral region of the substrate, for example, at 5 to 10 mm from the edges of the substrate, and the edge effect reduces the total flatness of the substrate, making the peripheral region of the substrate unsuitable for use in the integrated circuit, resulting in reduced yield.

To solve the problem, Korean Patent Publication No. 10-2012-0012099 discloses technology to cut a retainer ring that touches a membrane at a predetermined angle. However, this technology has problems with machining of the retainer ring itself, and excessively applied load caused by the reduced contact area of the retainer ring subjected to substantially strongest force to prevent the wafer from slipping out.

### DISCLOSURE OF THE INVENTION

### Technical Problem

The present disclosure is directed to providing a retainer ring of a new structure for reducing a wafer edge effect by differently dispersing the pressure applied to the retainer ring to part that touches the outer side surface of the wafer and part that does not touch the outer side surface.

### Technical Solution

In order to achieve the above and other object of the present disclosure, there is provided a retainer ring of a carrier head for a chemical polishing apparatus, including a first retainer ring member that touches an outer side surface of a wafer, a second retainer ring member that touches an outer side and top of the first retainer ring member, and a pressure reducing means for reducing the pressure transmitted from the second retainer ring member down to the first retainer ring member

### Advantageous Effects

The present disclosure can reduce a wafer edge effect by differently dispersing the pressure applied to the retainer ring to part that touches the outer side surface of the wafer and part that does not touch the outer side surface. Particularly, the wafer edge effect can be reduced by only changing the retainer ring structure without changing the chamber for applying the pressure to the retainer ring.

### BRIEF DESCRIPTION OF THE DRAWINGS

FIG. 1 is a cross-sectional view of a retainer ring of a carrier head for a chemical polishing apparatus according to an embodiment of the present disclosure.

FIG. 2 is a cross-sectional view illustrating a pressure profile of a retainer ring of a carrier head for a chemical polishing apparatus according to an embodiment of the present disclosure.

FIG. 3 is a diagram illustrating an edge phenomenon of a carrier head including a retainer ring according to an embodiment of the present disclosure.

FIG. 4 is a cross-sectional view of a retainer ring of a carrier head for a chemical polishing apparatus according to another embodiment of the present disclosure.

FIG. 5 is a cross-sectional view illustrating a pressure profile of a retainer ring of a carrier head for a chemical polishing apparatus according to another embodiment of the present disclosure.

FIG. 6 is a diagram illustrating an edge phenomenon of a carrier head including a retainer ring according to another embodiment of the present disclosure.

FIGS. 7 and 8 are diagrams illustrating an example of using a separate elastic layer (for example, a film or a membrane, a washer, etc.) as an elastic member on top or inside of a first retainer ring member 112, instead of rubber or a spring.

FIG. 9 is a perspective view of a retainer ring of a carrier head for a chemical polishing apparatus according to an embodiment of the present disclosure, when viewed from the top.

FIG. 10 is a perspective view of the retainer ring of FIG. 9, when viewed from the bottom.

FIG. 11 is an exploded perspective view of the retainer ring of FIG. 9.

FIG. 12 is a cross-sectional view of the retainer ring of FIG. 9, taken along the line IV-IV.

FIG. 13 is an enlarged view of section V in FIG. 12.

FIG. 14 is a diagram showing that a retainer ring of a carrier head for a chemical polishing apparatus according to an embodiment of the present disclosure is disposed on an edge area of a wafer on a pad.

FIG. 15 is a cross-sectional view illustrating a pressure profile of a retainer ring of a carrier head for a chemical polishing apparatus according to an embodiment of the present disclosure.

FIG. 16 is a diagram illustrating an edge phenomenon of a carrier head including a retainer ring according to an embodiment of the present disclosure.

### BEST MODE FOR CARRYING OUT THE INVENTION

Hereinafter, the present disclosure will be described with reference to the accompanying drawings.

In the following description, for a clear understanding of the present disclosure, a description of known technology about the features of the present disclosure is omitted herein. It is obvious that the following embodiments are described in detail to help the understanding of the present disclosure, but not intended to limit the scope of protection of the present disclosure. Accordingly, equivalent inventions that perform the same function as the present disclosure also will fall within the scope of protection of the present disclosure.

To solve the aforementioned problem, the present disclosure solves the wafer edge problem, by dividing the pressure profile of the retainer ring subjected to the pressure applied from the carrier head into an inner side that touches the outer side surface of the wafer and an outer side that does not touch the outer side surface of the wafer, and making the pressure of the inner side lower than that of the outer side.

In an embodiment of the present disclosure, the pressure profiles of the inner side/outer side (signifying the pressure actually applied to a pad) are different due to different elasticities in the same retainer ring, and a retainer ring of a carrier head for a chemical polishing apparatus according to an embodiment of the present disclosure is described below using the accompanying drawings.

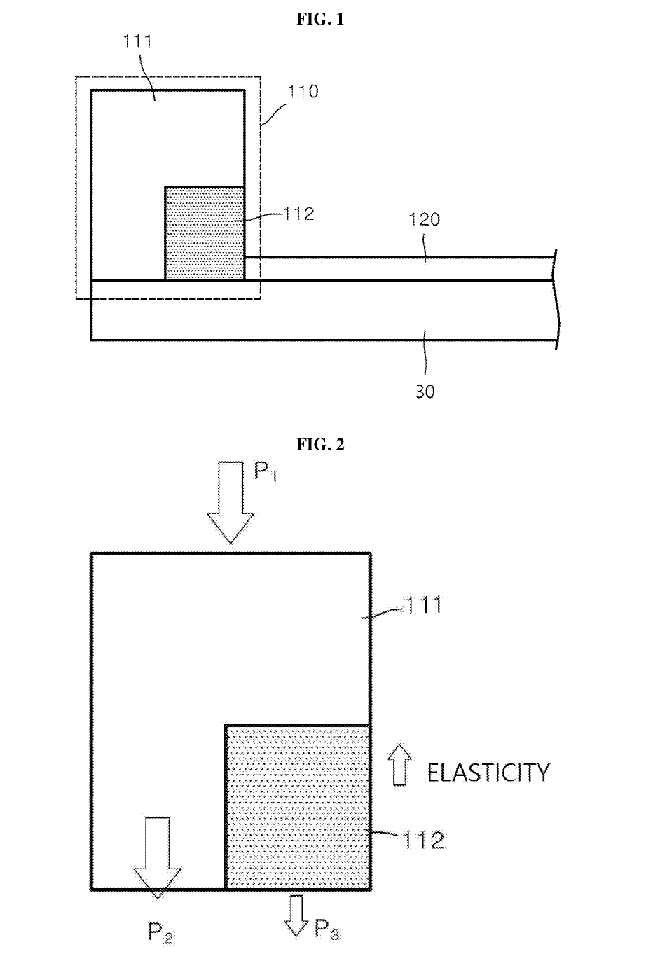

FIG. 1 is a cross-sectional view of a retainer ring of a carrier head for a chemical polishing apparatus according to an embodiment of the present disclosure.

Referring to FIG. 1, the retainer ring 110 according to an embodiment of the present disclosure includes part (hereinafter, a first retainer ring member (112)) that directly touches the outer side surface of a wafer 120, and a second retainer ring member 111 that touches the outer side and the top of the first retainer ring member 112 at the same time, and the pressure acting downwards from the carrier head is transmitted from the second retainer ring member 111 to the first retainer ring in order to prevent the wafer from slipping out. In this instance, the pressure reduces more at the first retainer ring member 112 than at the second retainer ring member 111, and in an embodiment of the present disclosure, an elasticity difference between the first retainer ring member 112 and the second retainer ring member 111 was used as pressure reducing means.

That is, in an embodiment of the present disclosure, there is provided technology to reduce the pressure transmitted from the second retainer ring member 111 down to the first retainer ring member by the first retainer ring member 112 of higher elasticity than the second retainer ring member 111.

FIG. 2 is a cross-sectional view illustrating a pressure profile of the retainer ring of a carrier head for a chemical polishing apparatus according to an embodiment of the present disclosure.

Referring to FIG. 2, the pressure P1 acts downwards from the carrier head (not shown), for example, through air. Applying the pressure to the retainer ring may be realized through various designs and methods, and the scope of the present disclosure is not limited to a particular pressing structure of the carrier head. The pressure is also transmitted to the underlying first retainer ring member 112 through the second retainer ring member 111, and thereby the second retainer ring member 111 and the first retainer ring member 112 are pressed down. In this instance, elasticity of the first retainer ring member 112 is higher than that of the second retainer ring member 111, and thereby the pressure P3 below the first retainer ring member 112 becomes lower than initial pressure P1 by the repulsive force of the elastic material. Further, the pressure P3 of the first retainer ring member 112 is lower than the pressure P2 of the second retainer ring member having lower elasticity.

Accordingly, the pressure profile in FIG. 2 can be summarized as below.

P2>P3

For pressure reduction, the pressure of the inner side area (the contact area with the outer side surface of the wafer) is lower in the same retainer ring subjected to a pressure as described above, thereby preventing wafer slippage and excessive edge polishing of the wafer during rotary polishing.

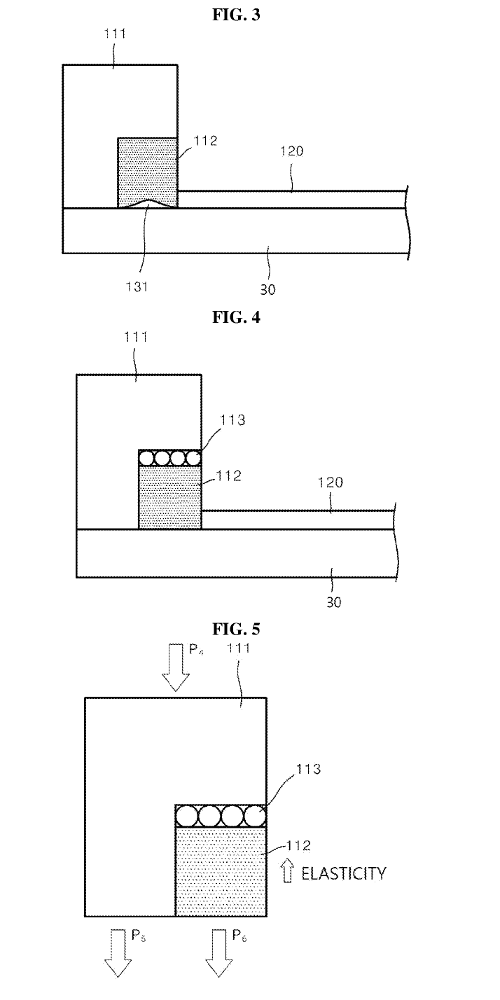

FIG. 3 is a diagram illustrating an edge phenomenon of the carrier head including the retainer ring according to an embodiment of the present disclosure.

Referring to FIG. 3, a certain area 131 of a pad 30 is rebounded by the second retainer ring member 111 subjected to higher pressure, but the rebound area 131 is not formed at the edge area of the wafer 120 and is formed at the first retainer ring member 112 of higher elasticity. As a result, it is possible to effectively prevent the excessive polishing problem caused by the pad rebound at the wafer edge area. Furthermore, an advantage is that a wafer fixing effect of the first retainer ring member 112 by the rebounded pad is further improved.

In another embodiment of the present disclosure, as opposed to adjusting the elasticity of the retainer ring itself, pressure adjustment is accomplished by providing the first retainer ring member with an elastic material, for example, rubber. In this instance, the first retainer ring member may have the same elasticity as the second retainer ring member.

FIG. 4 is a cross-sectional view of a retainer ring of a carrier head for a chemical polishing apparatus according to another embodiment of the present disclosure.

Referring to FIG. 4, the retainer ring according to another embodiment of the present disclosure includes the first retainer ring member 112 that directly touches the outer side surface of the wafer 120, and the second retainer ring member 111 that does not directly touch the wafer. However, dissimilar to the previous embodiment having the first retainer ring member with higher elasticity per se, in this embodiment, a separate elastic member 113 is provided between the first retainer ring member 112 and the second retainer ring member 111, i.e., on or inside the first retainer ring member 112.

In the present disclosure, the elastic member 113 includes any material having higher elasticity than the first retainer ring member 112 or the second retainer ring member 111, and this falls within the scope of the present disclosure. Furthermore, at least one elastic member 113 is provided on the top and/or the side of the first retainer ring member 112, and for a uniform pressure profile, it is desirable to use at least one elastic member 113.

FIG. 5 is a cross-sectional view illustrating a pressure profile of the retainer ring of a carrier head for a chemical polishing apparatus according to another embodiment of the present disclosure.

Referring to FIG. 5, the pressure P6 of the first retainer ring member 112 acting on the pad is reduced by the elastic member 113 such as rubber, and as a result, the pressure P6 of the first retainer ring member 112 acting on the pad is lower than the pressure P5 of the second retainer ring member 111 acting on the pad.

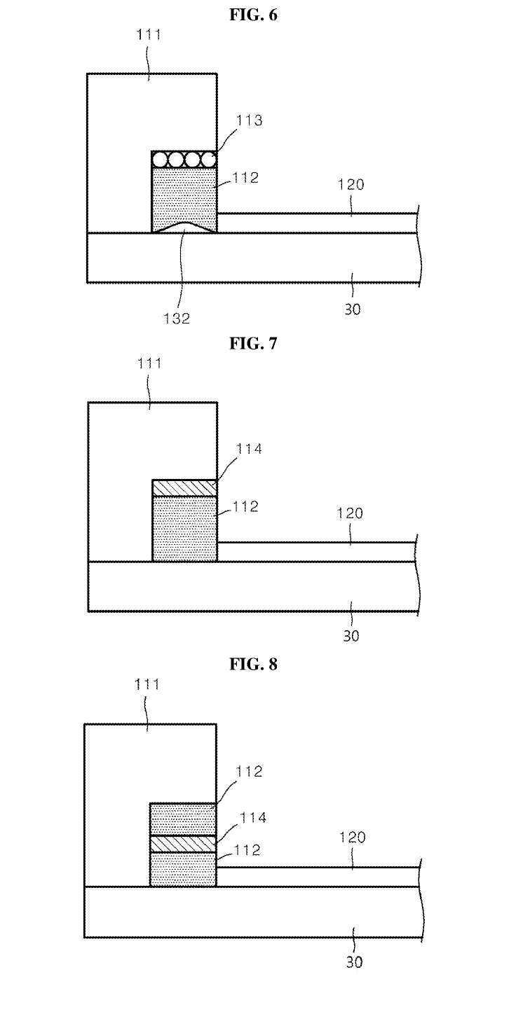

FIG. 6 is a diagram illustrating an edge phenomenon of the carrier head including the retainer ring according to another embodiment of the present disclosure.

Referring to FIG. 6, by using the elastic member 113 as pressure reducing means for reducing the pressure transmitted from the second retainer ring member 111 down to the first retainer ring member 112, it is possible to effectively prevent the excessive polishing problem caused by the pad rebound at the wafer edge area as shown in FIG. 3. Furthermore, an advantage is that a wafer fixing effect of the first retainer ring member 112 by the rebounded pad is further improved.

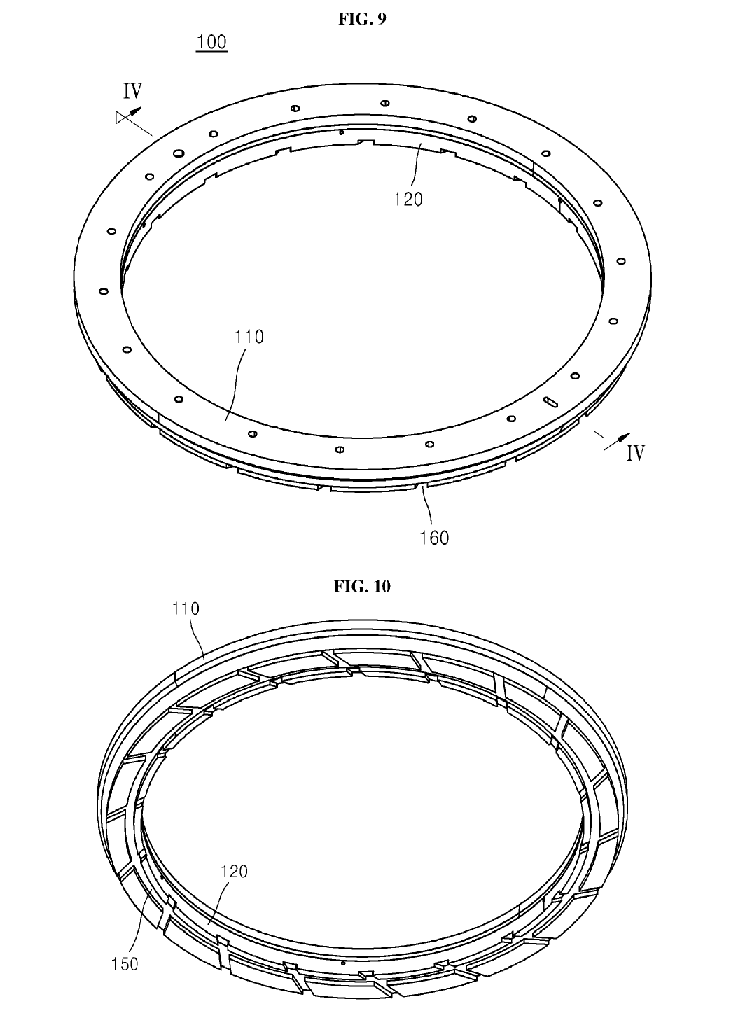

FIGS. 7 and 8 are diagrams illustrating an example of using a separate elastic layer (for example, a film or a membrane, a washer, etc.) as the elastic member on or inside the first retainer ring member 112, instead of rubber or a spring.

Referring to FIGS. 7 and 8, there is disclosed technology to reduce the pressure acting down only at the first retainer ring member 112 by using an elastic layer 114 made of any material having higher elasticity than the first retainer ring member 112 on or inside the first retainer ring member 112.

### MODE FOR CARRYING OUT THE INVENTION

Below is a description of specific embodiments of the retainer ring according to the present disclosure.

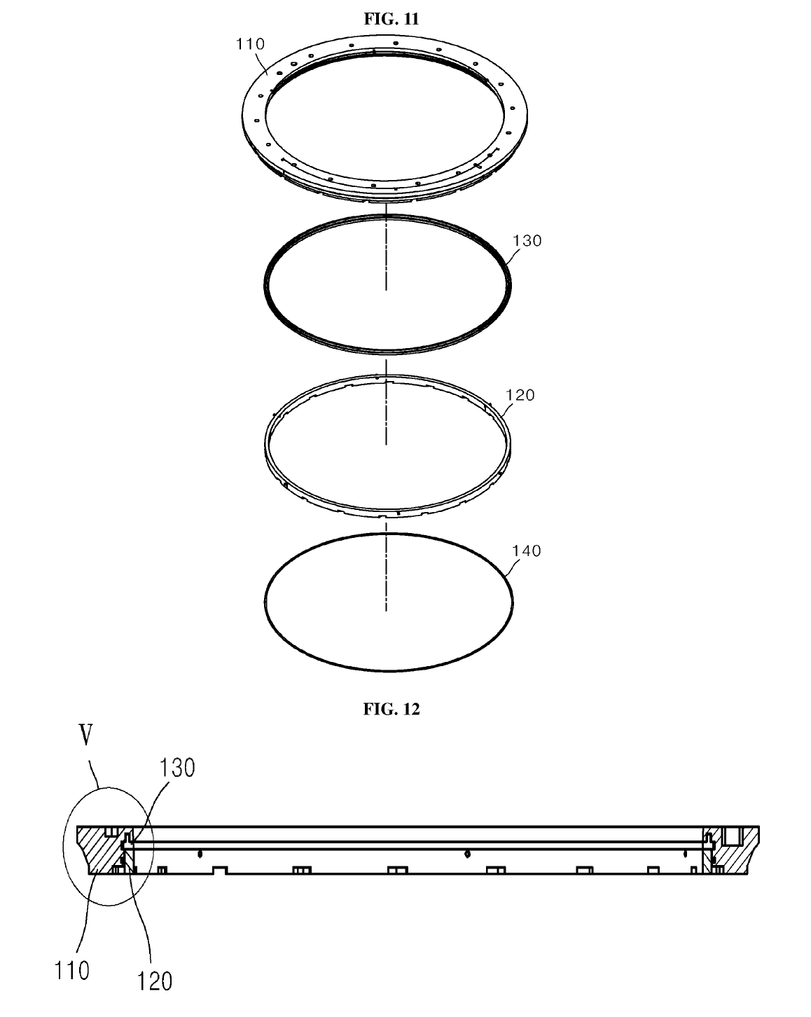

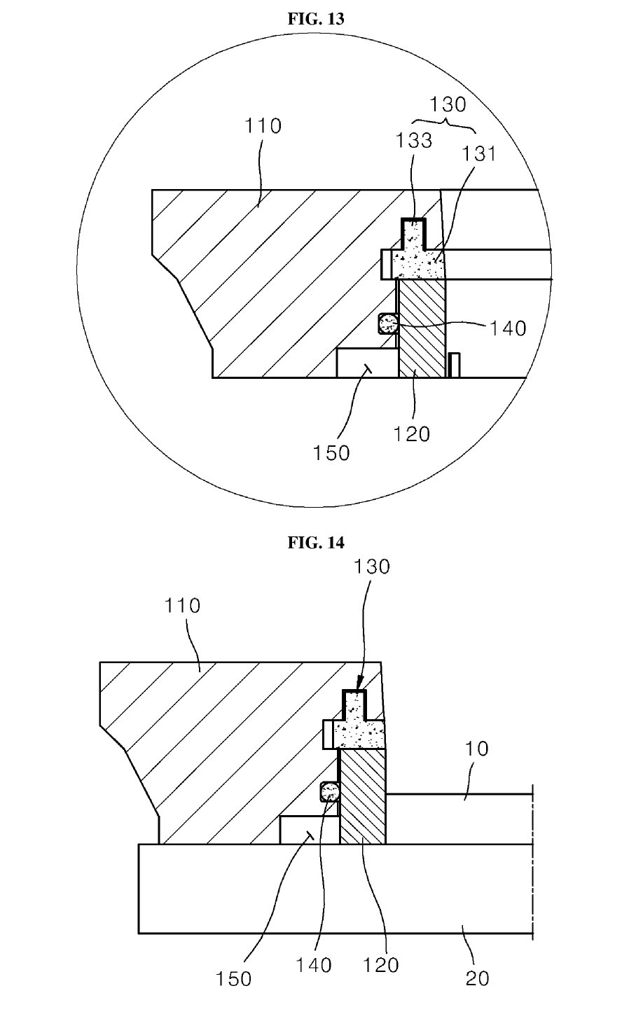

FIG. 9 is a perspective view of a retainer ring of a carrier head for a chemical polishing apparatus according to an embodiment of the present disclosure when viewed from the top, FIG. 10 is a perspective view of the retainer ring of FIG. 9 when viewed from the bottom, FIG. 11 is an exploded perspective view of the retainer ring of FIG. 9, FIG. 12 is a cross-sectional view of the retainer ring of FIG. 9 taken along the line IV-IV, and FIG. 13 is an enlarged view of section V in FIG. 12.

Referring to FIGS. 9 to 11, the retainer ring 100 according to an embodiment of the present disclosure includes part (hereinafter, a first retainer ring member (120)) that directly touches the outer side surface of a wafer 10, a second retainer ring member 110 that directly touches with the outer side and the top of the first retainer ring member 120 at the same time, an elastic member 130 placed between the second retainer ring member 110 and the first retainer ring member 120, i.e., on or inside the first retainer ring member 120, a sealing member 140 placed between the second retainer ring member 110 and the first retainer ring member 120, and a buffer area 150 formed at the lower end of the second retainer ring member 110 adjacent to the first retainer ring member 120.

The elastic member 130 includes any material having higher elasticity than the second retainer ring member 110 or the first retainer ring member 120, and this falls within the scope of the present disclosure. Furthermore, at least one elastic member 130 is provided on the top and/or the side of the first retainer ring member 120, and for a uniform pressure profile, it is desirable to use at least one elastic member.

A detailed structure of the elastic member 130 is as follows. The elastic member 130 includes a first elastic portion 131 placed on and in direct contact with the upper surface of the first retainer ring member 120, and a second elastic portion 133 placed on the upper surface of the first elastic portion 131 and having a smaller width than the first elastic portion 131. That is, the entire cross-sectional shape of the elastic member 130 may be the shape of ‘⊥’. Here, the second elastic portion 133 may have a structure in which the second elastic portion 133 is inserted into a groove formed in the second retainer ring member 110. However, besides, a straight line shape or a block shape is possible, and so long as the elastic member 130 is placed on or inside the first retainer ring member 120 and has higher elasticity than the first retainer ring member 120, this falls within the scope of the present disclosure.

Furthermore, although not shown, the second retainer ring member 110 is connected by mechanical connecting means (for example, a pin or a protrusion) of the first retainer ring member 120, and is mechanically linked and rotates.

The sealing member 140 is placed between the inner side of the second retainer ring member 110 and the outer side of the first retainer ring member 120. Specifically, the sealing member 140 may have a structure in which the sealing member 140 is inserted fixedly into a sealing groove formed on the inner surface of the second retainer ring member 110. Through this connection structure, it is possible to prevent the slurry from flowing through a very small space between the inner side of the second retainer ring member 110 and the first retainer ring member 120 in the wafer polishing process. Although in this drawing, the sealing member 140 is set such that the sealing member 140 is spaced apart from the buffer area 150 and the elastic member 130, the sealing member 140 may be adjacent to the buffer area 150 or the elastic member 130, and this may also be expressed as the sealing member 140 disposed between the buffer area 150 and the elastic member 130.

The buffer area 150 is an empty space of a ring shape formed at the inner lower end of the second retainer ring member 110, and is adjacent to the lower end of the outer side surface of the first retainer ring member 120. Through this structure, the pressure acting downwards through the second retainer ring member 110 undergoes a buffer process through the buffer area 150, and is transmitted to the first retainer ring member 120.

The present disclosure allows the pressure acting downwards from the carrier head to be transmitted from the second retainer ring member 110 to the second retainer ring 120, in order to prevent the wafer 10 from slipping out. In this instance, the transmitted pressure reduces at the first retainer ring member 120 than at the second retainer ring member 110, and an elasticity difference between the second retainer ring member 110 and the first retainer ring member 120 was used as pressure reducing means.

That is, the present disclosure provides the first retainer ring member 120 with the elastic member of higher elasticity than the second retainer ring member 110 to reduce the pressure transmitted to the first retainer ring member 120.

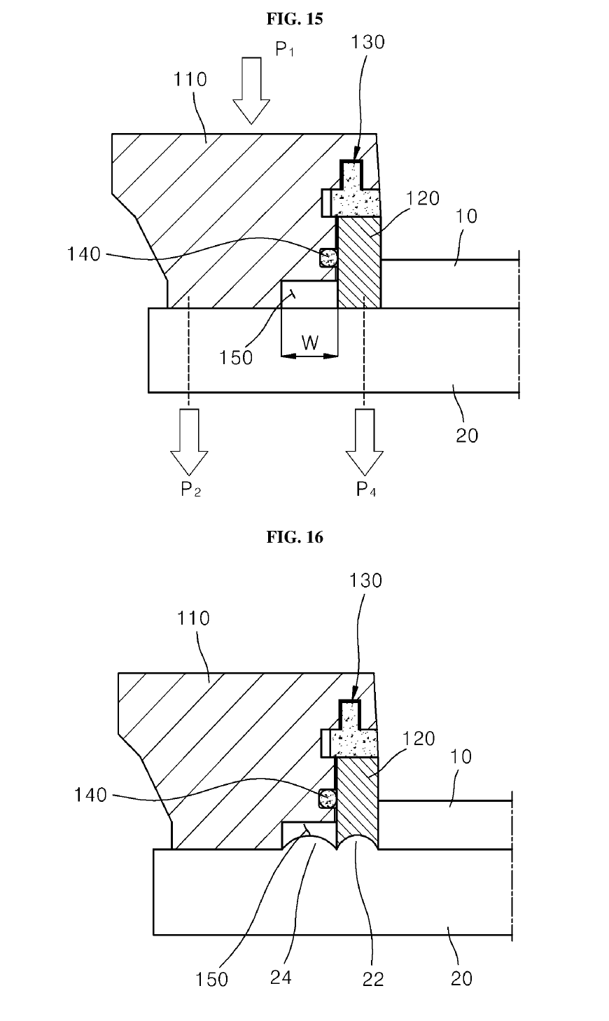

FIG. 15 is a cross-sectional view illustrating a pressure profile of the retainer ring of a carrier head for a chemical polishing apparatus according to an embodiment of the present disclosure.

Referring to FIG. 15, the pressure P1 acts downwards from the carrier head (not shown), for example, through air. Applying the pressure to the retainer ring may be realized through various designs and methods, and the scope of the present disclosure is not limited to a particular pressing structure of the carrier head.

The pressure from the top may be directly transmitted to the underlying pad 20 through the second retainer ring member 110, or may be transmitted to the pad 20 through the second retainer ring member 110, the elastic member 130 and the first retainer ring member 120, and thereby the first retainer ring member 120 and the second retainer ring member 110 are pressed down.

Here, the pressure P4 of the first retainer ring member 120 acting on the pad is reduced by the elastic member 130 such as rubber, and as a result, the pressure P4 of the first retainer ring member 120 acting on the pad is lower than the pressure P2 of the second retainer ring member 110 acting on the pad.

Furthermore, it is possible to effectively control the profile of pad rebound induced by the applied pressure, based on the width w of the buffer area. For example, when the width w is large, the maximum pad rebound position can be set within the width w of the buffer area.

FIG. 16 is a diagram illustrating an edge phenomenon of the carrier head including the retainer ring according to an embodiment of the present disclosure.

Referring to FIG. 16, some areas 22, 24 of the pad 20 are rebounded by the second retainer ring member 110 subjected to higher pressure, but the rebound areas 22, 24 are formed at the lower part of the buffer area 150 and/or the first retainer ring member 120, not the edge area of the wafer 10. Here, the buffer area 150 placed on the outer side of the rebound area 22 functions in reducing the impact transmitted to the rebound area 22 by the pressure P2 transmitted to the lower side of the first retainer ring member, and through this, it is possible to prevent excessive rebound from being formed at the lower part of the first retainer ring member 120.

As a result, the excessive polishing problem caused by the pad rebound at the wafer edge area can be effectively prevented. Furthermore, an advantage is that a wafer fixing effect of the first retainer ring member 120 is further improved by the rebounded pad.

That is, by using the elastic member 130 as pressure reducing means for reducing the pressure transmitted from the second retainer ring member 110 down to the first retainer ring member 120, it is possible to effectively prevent the excessive polishing problem caused by the pad rebound at the wafer edge area. Furthermore, an advantage is that a wafer fixing effect of the first retainer ring member 120 is further improved by the rebounded pad.

While the present disclosure has been hereinabove described with respect to the disclosed embodiments, the present disclosure is not limited thereto and various modifications can be made without departing from the scope and spirit of the present disclosure.

### INDUSTRIAL APPLICABILITY

The present disclosure relates to a retainer ring of a carrier head for a chemical polishing apparatus and a carrier head comprising the same, and is industrially applicable.

1. A retainer ring of a carrier head for a chemical polishing apparatus comprising:
a first retainer ring member contacting an outer side surface of a wafer;
a second retainer ring member contacting an outer side and top of the first retainer ring member; and
a pressure reducing means for reducing the pressure transmitted from the second retainer ring member down to the first retainer ring member.

2. The retainer ring of a carrier head for a chemical polishing apparatus of claim 1, wherein the pressure reducing means is elasticity of the first retainer ring member higher than the second retainer ring member.

3. The retainer ring of a carrier head for a chemical polishing apparatus of claim 1, wherein the pressure reducing means is an elastic member provided between the first retainer ring member and the second retainer ring member.

4. The retainer ring of a carrier head for a chemical polishing apparatus of claim 3, wherein the elastic member includes rubber or a spring.

5. The retainer ring of a carrier head for a chemical polishing apparatus of claim 3, wherein at least one elastic member is provided on the first retainer ring.

6. The retainer ring of a carrier head for a member is an elastic layer provided on or inside the retainer ring.

7. A carrier head for a chemical polishing apparatus comprising the retainer ring of a carrier head for a chemical polishing apparatus of claim 1,
wherein the pressure reducing means is an elastic member that is inserted between the second retainer ring member and the first retainer ring member,
wherein elasticity of the pressure reducing means is greater than elasticity of the first and second retainer ring members, so that the retainer ring of the carrier head divides a pressure applied from the top and transmits it to an underlying pad.

8. The retainer ring of a carrier head for a chemical polishing apparatus of claim 7, wherein the retainer ring of the carrier head for a chemical polishing apparatus further includes a sealing member placed between the second retainer ring member and the first retainer ring member.

9. The retainer ring of a carrier head for a chemical polishing apparatus of claim 8, wherein the sealing member is placed between the elastic member and a buffer area.

10. The retainer ring of a carrier head for a chemical polishing apparatus of claim 7, wherein the elastic member comprises:
a first elastic portion placed on and in direct contact with an upper surface of the first retainer ring member; and
a second elastic portion placed on an upper surface of the first elastic portion and having a smaller width than the first elastic portion.

11. The retainer ring of a carrier head for a chemical polishing apparatus of claim 7, wherein at least one elastic member is provided on the first retainer ring.

12. The retainer ring of a carrier head for a chemical polishing apparatus of claim 7, wherein the elastic member is an elastic layer provided on or inside the retainer ring.

13. A carrier head for a chemical polishing apparatus comprising the retainer ring of a carrier head for a chemical polishing apparatus of claim 1.
